(19) United States
(12) Patent Application Publication
(10) Pub. No.: US 2007/0114658 A1
(43) Pub. Date: May 24, 2007

(54) Integrated Circuit Micro-Cooler with Double-Sided Tubes of a CNT Array

(76) Inventors: Carlos Dangelo, Los Gatos, CA (US); Darin Olson, Menlo Park, CA (US)

Correspondence Address: GLENN PATENT GROUP, 3475 EDISON WAY, SUITE L, MENLO PARK, CA, 94025, US

(21) Appl. No.: 11/532,894

(22) Filed: Sep. 18, 2006

Related U.S. Application Data
(63) Continuation-in-part of application No. 10/925,824, filed on Aug. 24, 2004, now Pat. No. 7,109,581.

(51) Int. Cl. H01L 23/34

(52) U.S. Cl. 257/720

(57) ABSTRACT

Heat sink structures employing carbon nanotube or nanowire arrays exposed from both opposite surfaces of the structure to reduce the thermal interface resistance between an integrated circuit chip and the heat sink are disclosed. In one embodiment, the nanotubes are cut to essentially the same length over the surface of the structure. Carbon nanotube arrays are combined with a thermally conductive metal filler disposed between the nanotubes. This structure produces a thermal interface with high axial and lateral thermal conductivities.

### CROSS-REFERENCE TO RELATED APPLICATION

This application is a continuation-in-part of U.S. patent application Ser. No. 10/925,824 now U.S. Pat. No. 7,109,581, the entirety of which is incorporated herein by this reference thereto.

### BACKGROUND OF THE INVENTION

1. Technical Field

The invention relates to the removal of heat generated by an integrated circuit and the components used in chip assembly and packaging to facilitate said heat removal. More specifically, the invention relates to the application of self-assembled nano-structures for improving the performance of heat sink structures coupled to integrated circuit devices, and more specifically to carbon nanotubes protruding over the surface of both sides of a heat sink structure.

2. Discussion of the Prior Art

Prior art techniques that are used to cool semiconductor ICs incorporate the use of large and expensive chip packaging having externally mounted, finned heat sinks coupled to the ceramic or plastic encapsulated IC chip. As the speed and density of modern integrated circuits increase, the power generated by these chips also increases, often in geometric proportion to increasing density and functionality. In the video processing and CPU application areas, the ability to dissipate the heat being generated by current ICs is becoming a serious limitation in the advance of technology. In the current art, relatively large interface-thermal-resistances are added when the die is attached to a heat spreader, heat pipe, or heat sink. These multiple interfaces have the undesired side effect of increasing total die-to-heat sink resistance and making heat transfer more difficult.

FIG. 1 (prior art) is a cross section schematic view of a simplified integrated circuit structure. A transistor structure 102 is formed near the top surface of a substrate 100. Electrical interconnects 106 are used to make contact with the transistor 102 and numerous other similar devices (not shown) on the substrate 100. Solder balls 104 are used to complete the interconnect of the integrated circuit to a printed circuit board or wire leadframe. This type of package is often referred to as a flip chip device. In the current art, heat generated by the transistor 102 is extracted through the substrate 100 to the back surface of the chip. A heat transfer bonding layer 108 may be used to enhance heat conduction by reducing interfacial heat transfer resistance created by air gaps and surface irregularities. Typically, this layer may be composed of a thermal grease or thermally conductive epoxy. These materials, while better than solid surface/surface contact, still have a relatively poor thermal conductivity when compared to solid metals. As a result, the backside chip surface interface still presents a significant thermal resistance, which limits the power that can be extracted from the chip.

U.S. patent application publication number US2003/0117770 discloses a process of forming a thermal interface that employs carbon nano-tubes to reduce thermal resistance between an electronic device and a heat sink. Bundles of aligned nano-tubes receive injected polymeric material in molten form to produce a composite which is placed between the electronic device and the heat sink. The nano-tubes are aligned parallel to the direction of heat energy. However, the polymeric filler does little to spread heat laterally, potentially creating localized hot spots on the device surface. The use of bundles of aligned carbon nano-tubes may result in reduced thermal conduction as well. Theoretical molecular dynamics simulations have shown that isolated carbon nano-tubes exhibit unusually high thermal conductivity, but that the thermal conductivity degrades by an order of magnitude when carbon nano-tube bundles are formed with tube-to-tube contacts (see for example Savas Berber et al, Physics Review Letters, 84, no. 20, 4613, (May 2000)).

U.S. patent application publication number US2003/231471 discloses an integrated circuit package that uses single wall or double wall carbon nano-tube arrays grown subsequent to the deposition of CVD diamond films. Due to the roughness of CVD diamond films, carbon nano-tubes are used to aid in making thermal contact between the surfaces of the circuit silicon die and of the integrated heat spreader. The interstitial voids between the nano-tubes are not filled to maintain flexibility. The '471 disclosure, however, fails to provide any method to reduce matting and nano-tube to nano-tube contact, which reduces the effective thermal conductivity of the structure. Although CVD diamond films are good conductors, they may not be thermally compatible, from an expansion perspective, with a number of other metallic materials used in various heat sink structures. Additionally, commonly known techniques for growing carbon nano-tubes preclude carbon nanotube deposition directly on a silicon circuit die because these techniques require temperatures in the range of 700 to 800° C. Exposing a completed circuit die to these elevated temperatures is not a recommended practice.

Typically, there is a need to make contact between two opposite surfaces of a micro-cooler, i.e. on one side to the integrated circuit and on the other side to a heat sink to spread the heat away from the hot surface. What is needed is a method and structure by which interface resistances are minimized by integrating several thermal components to maximize heat transfer from hot surfaces on the integrated circuit.

### SUMMARY OF THE INVENTION

The invention provides a micro-cooler device structure containing a heat sink body having a heat sink surface and a plurality of individually separated, rod-like nano-structures for transferring thermal energy from a surface of at least one integrated circuit chip to the heat sink surface. The plurality of individually separated, rod-like nano-structures are disposed between the heat sink surface and the heat generating surface. A thermally conductive material is disposed within interstitial voids between the rod-like nano-structures.

In one embodiment of the invention, a method for fabricating a micro-cooler device includes fashioning a shallow cavity in a mounting surface of a heat sink body, growing rod-like nano-structures within the shallow cavity, and depositing a thermally conductive material in interstitial voids between the rod-like nano-structures, and further providing a protrusion of the edges, or ends, of the rod-like nano-structures from opposite surfaces of the structure. In another embodiment, the rod-like nano-structures are cut to an essentially identical length over a surface of the micro-cooler.

### BRIEF DESCRIPTION OF THE DRAWINGS

FIG. 1 (prior art) is a cross section schematic view of an integrated circuit structure;

FIG. 2 is a schematic side view of integrated micro-cooler device attached to a flip chip integrated circuit according to the invention;

FIG. 3 is a schematic side view of integrated micro-cooler device attached to multiple flip chip integrated circuits according to the invention;

FIG. 4 is a cross section schematic view of a finned integrated micro-cooler device showing the details of construction according to the invention;

FIG. 5 is a cross section schematic view of an integrated micro-cooler device having internal flow channels according to the invention;

FIG. 6 is an electron microscope photo of carbon nano-tubes according to the invention;

FIG. 7 is a cross section schematic view of an integrated micro-cooler device bonded to multiple flip chip integrated circuits according to the invention;

FIG. 8 is a process flow diagram illustrating the steps for manufacture of a finned integrated micro-cooler device according to the invention;

FIG. 9 is a process flow diagram illustrating the steps for manufacture of an integrated micro-cooler device having internal flow channels according to the invention;

FIG. 10 is a partial cross section view of the nano-structure array subsequent to a planarization process according to the invention;

FIG. 11 is a schematic cross-section of an apparatus where the edges of the carbon nanotubes are exposed over the surface of the filler material according to the invention;

FIG. 12 is a schematic cross-section of the disclosed apparatus showing the carbon nanotubes cut to uniform length over the surface of the filler material according to the invention;

FIG. 13 is a schematic cross-section of the disclosed apparatus with the growth substrate removed according to the invention;

FIG. 14 is a schematic cross-section of the disclosed apparatus showing the carbon nanotubes of uniform length over each of the two opposite surfaces of a partially removed support medium according to the invention; and

FIG. 15 is a flowchart diagram of the process of exposing the carbon nanotubes to a uniform length over two surfaces of a partially removed support medium according to the invention.

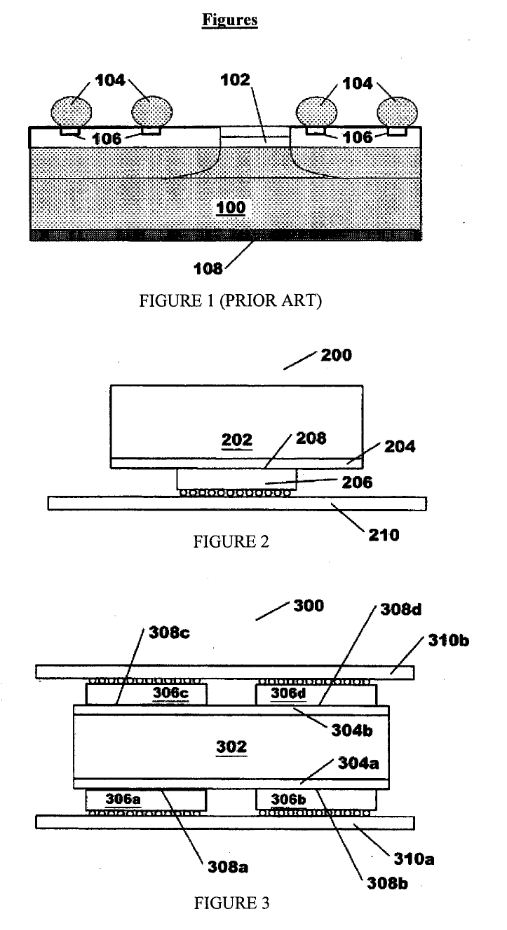

### DETAILED DESCRIPTION OF THE INVENTION

FIG. 2 is a schematic side view 200 of integrated micro-cooler device 202 attached to a flip chip integrated circuit 206 according to an embodiment of the invention. The integrated micro-cooler device 202 is a separate structure from the chip 206 that contains highly conductive, self-assembled nano structures that are integrated with heat sinking devices. It provides a low thermal resistance path for heat transferred from a surface 208 of the integrated circuit chip 206 mounted on a circuit board 210 below the thermal interface layer 204 provides a low resistance interface that contains nano-structures which enhance heat conduction from the chip 206, reduce the impact of local hot spots in the chip 206, and laterally conduct heat to a heat sink structure 202 having a greater footprint than that of the chip 206. Structural details of micro-cooler device 202 are disclosed below. The chip 206 and micro-cooler 202 may be bonded together using eutectic layers or thermal bonding adhesives (not shown), as is known to those skilled in the art. Additionally, the micro-cooler device 202, integrated circuit chip 206, and circuit board 210 may be held together with mechanical straps, clips, or holding devices (not shown).

FIG. 3 is a schematic side view 300 of an integrated micro-cooler device 302 attached to multiple flip chip integrated circuits (306a-306d) according to an embodiment of the invention. In this embodiment, both the upper and lower surfaces of the micro-cooler device 302 are used to remove heat energy from the flip chip ICs 306a-306d. Chips 306a and 306b, mounted on a printed circuit board 310a, sink heat from the surfaces 308a and 308b, to device 302 via interface layer 304a. Chips 306c and 306d, mounted on a printed circuit board 310b, sink heat from the surfaces 308c and 308d, to a device 302 via an interface layer 304b. The chips 306 and micro-cooler 302 may be bonded together using eutectic layers or thermal bonding adhesives (not shown), as is known to those skilled in the art. Additionally, the micro-cooler device 302, integrated circuit chips 306, and circuit boards 310 may be held together with mechanical straps, clips, or holding devices (not shown). Although the embodiment shown in FIG. 3 contains four integrated circuits, it should be evident to those of ordinary skill in the art that any number of additional integrated circuit flip chips 306 may be added by increasing the scale of the device 302.

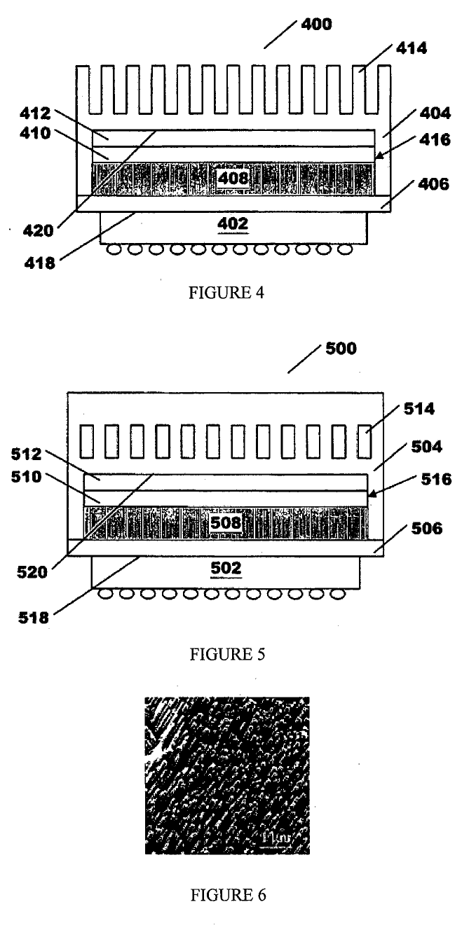

FIG. 4 is a cross section schematic view of a finned integrated micro-cooler device 400 showing the details of construction according to an embodiment of the invention. The device 400 comprises a heat sink body 404 for extracting thermal energy from the surface 418 of a flip chip 402. Heat energy is delivered to a heat sink surface 420 by an enhanced heat transfer interface structure containing layers 408, 410, and 412. The heat sink body 404 is fabricated with fins 414 (or pin shaped structures) to enhance heat extraction by convection, which is typically forced air flow generated by a fan or other device. However, natural convection may also be employed if suitable. Also, the fins 414 may be immersed in a liquid, such as water or another liquid phase coolant, for removal of high energy fluxes. The heat sink body 404 may be made from silicon, metals, or heat conductive ceramics. Metals, such as copper or aluminum, are preferred but structures fashioned from silicon substrates, or a metal coated ceramic, may also be used. If silicon is used, the fin surfaces may be coated with a metal to enhance lateral heat conduction. A heat spreading cavity 416 is fashioned within the heat sink body 404, by methods well known to those skilled in the art, to contain heat transfer interface layers 408, 410, and 412.

A layer 408 contains individually separated, rod-like nano-structures that provide very high thermal conductivity to reduce interface contact resistance. These structures may be comprised of metallic nano-wires or, preferably, multi-wall carbon nano-tubes (MWCNT) or multi-wall carbon nano-fibers. Metallic nanowires, for example Au, Cu, Ni, zinc oxide, and metal borides, are metal crystals having the shape of a wire with dimensions comparable to the phonon mean free path, usually tens of nanometers at room temperature, to benefit from quantum confinement phenomena, thus allowing for efficient heat transport characteristics and thermal contact. In one example, metal boride nanowires provides good thermal contact resistance because low ohmic contact resistance has been demonstrated with Ni electrodes. Preferably, the MWCNTs are oriented with their longitudinal axis approximately perpendicular to surfaces 420 and 418, parallel to the direction of heat flow. MWCNTs have very high on axis thermal conductivity, generally within the range of 800 to 3000 W/m-° K. TTheir thermal conductivity may be up to a factor of two better than solid CVD diamond films. They are preferably grown on the micro-cooler 400 surface as an array of free standing, vertically aligned, individually separated carbon nanotubes (or nanofibers) that occupy between about 15 and 40% of the surface from which they are grown. In some embodiments, the MWCNT are grown by plasma enhanced CVD (PECVD) growth methods. For example, the methods described by Jun Li et al. (Applied Physics Letters, vol. 81, no. 5 (July 2002) and L. Delzeit et al. (J. Appl. Physics 91, 6027 (May 2002))) can be used. However, while axial thermal conduction of CNTs is very high, lateral thermal conduction in the non-axial direction from nano-tube to nano-tube is not as good. In fact, it has been found that lateral contact between axially aligned nano-tubes can reduce their effective axial thermal conductivity. If the number of carbon nano-tubes attached to substrate is too high, for example, >40% CNT density, Van der Waals force create a bundle or mat situation, resulting in poor thermal conduction. If, on the other hand the coverage density is too low, for example, <15%, thermal conduction is also lower due to the reduced number of conducting nano-tubes. A preferred range a coverage density is between about 15 and 40%, with 25% to 40% being most preferred. Thus, as opposed to a bundle or mat of CNTs, vertically aligned, individually separated, parallel CNTs with coverage between about 15 and 40%, can provide better overall thermal conduction.

To improve lateral heat conduction, a thermally conductive material is placed within the interstitial voids between the MWCNTs. The thermally conducting material provides lateral heat conduction within the nano-tube containing layer. Lateral heat conduction facilitates the spreading of heat from a relatively small silicon die surface to the much larger surface area of the heat sink body 404. It also reduces localized hot spots on the surface 418 of the chip 402. The thermally conductive material may be a metal or metal alloy, thermally conductive ceramics, CVD diamond, or thermally conductive polymers. Preferably, the thermally conductive material is a metal, such as copper, aluminum, silver, gold, or their alloys. Of the metal materials, copper and copper alloys are the most preferable. This is generally due to the high thermal conductivity, ease of deposition via electroplating or electrochemical deposition, and low cost. Copper electroplating is well known to those skilled in the art of dual Damascene processing, which is common in the production of modern integrated circuits. Depending on the thermal conductivity of the thermally conductive filler material, the layer 408 is typically between 50 and 1000 microns in thickness.

Another desirable aspect of using metal as a filler material is that it is significantly lower in hardness than the MWCNTs. In some embodiments, planarization of the layer 408 is used to maintain flatness for good long range contact. However, short range surface irregularities on the order of a few microns can also contribute significantly to interface thermal resistance. It is therefore desirable to have some portion of the MWCNTs extend from the bulk of the layer 408, so that the exposed ends may conform to these surface irregularities and improve thermal contact. When the layer 408 is planarized, the softer metal material is eroded more than the harder nanotubes, resulting in an undercutting of the metal layer. This undercutting leaves a portion of the nanotubes extending from the composite layer 408. This undercutting automatically occurs when the layer 408 is planarized with CMP (chemical-mechanical planarization) or electrochemical etching techniques. An additional optional bonding layer 406 can be added, if eutectic metal bonding between the chip 402 and the layer 408 is desired. In this case, the exposed nanotube ends protrude into this layer and may extend through it. Preferably, the bonding layer 406 is a eutectic metal, but thermal polymer based bonding compounds may also be used. The layer 412 is an interface material which can be used with a silicon heat sink body 404. Typically, the layer 412 is composed of silicon nitride compounds. For metal heat sink bodies 404, the layer 412 is optional and is only required to aid in the adhesion of the catalyst metal layer 410. The metal catalyst layer 410 is used to initiate and control growth of the nanotubes in the layer 408. The metal catalyst layer 410 may chosen from among Ti, Co, Cr, Pt, Ni, and their alloys. Preferably, the metal catalyst layer 410 comprises Ni and Ni alloys. Further process conditions related to these layers are discussed below.

FIG. 5 is a cross section schematic view of an integrated micro-cooler device 500 having internal flow channels 514 according to an embodiment of the invention. The device 500 comprises a heat sink body 504 for extracting thermal energy from the surface 518 of a flip chip 502. Heat energy is delivered to the heat sink surface 520 by an enhanced heat transfer interface structure containing layers 508, 510, and 512. Layers 508-512 reside in a heat spreading cavity 516 fashioned in a body 504. In this embodiment, the heat sink body 504 contains enclosed flow passages 514 that remove the thermal energy transferred from the chip 502. Both liquid and gas cooling is possible but, for this embodiment, liquid cooling is preferred due to the specific heat capacity of a liquid coolant, such as water. A refrigerant may also be used in very high heat removal systems, or where sub-ambient junction temperatures are required for very high speed processors. Due to the high heat fluxes encountered by such systems, the low thermal resistances provided by embodiments of the invention become essential to reliable operation. The layers 506-512 have the same function and are composed of the same materials as described above for corresponding layers 406-412.

FIG. 6 is an electron microscope photo of carbon nano-tubes according to an embodiment of the invention. In this figure, the aligned, individually separated, parallel nature of the MWCNTs is evident. Also evident are the interstitial voids between nanotubes that need to be filled for good lateral heat conduction.

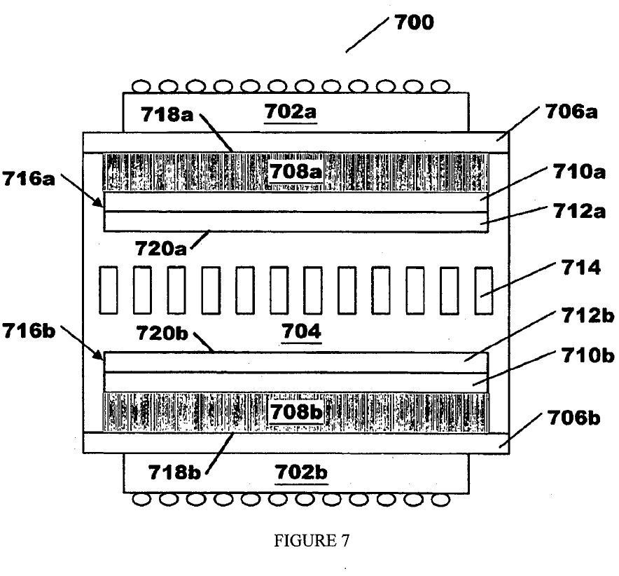

FIG. 7 is a cross section schematic view of an integrated micro-cooler device 700 attached to multiple flip chip integrated circuits according to an embodiment of the invention. The device 700 comprises a heat sink body 704 for extracting thermal energy from heat generating multiple flip chips 702a and 702b. Heat energy is delivered to the heat sink surfaces 720a and 720b by an enhanced heat transfer interface structure containing layers 508a-512a and 508b-512b. The layers 508a-512a and 508b-512b reside in heat speading cavities 716a and 716b, respectively. In this embodiment, the heat sink body 704 contains enclosed flow passages 714 that remove the thermal energy transferred from the chip 502. For this embodiment, due to the increased heat loading, liquid cooling is preferred due to the specific heat capacity of a liquid coolant such as water. A refrigerant may also be used for removal of the high heat loads, or where sub ambient junction temperatures are required for very high speed processors. The layers 706a-712a and 706b-712b have the same function and are composed of the same materials as described above for corresponding layers 406-412.

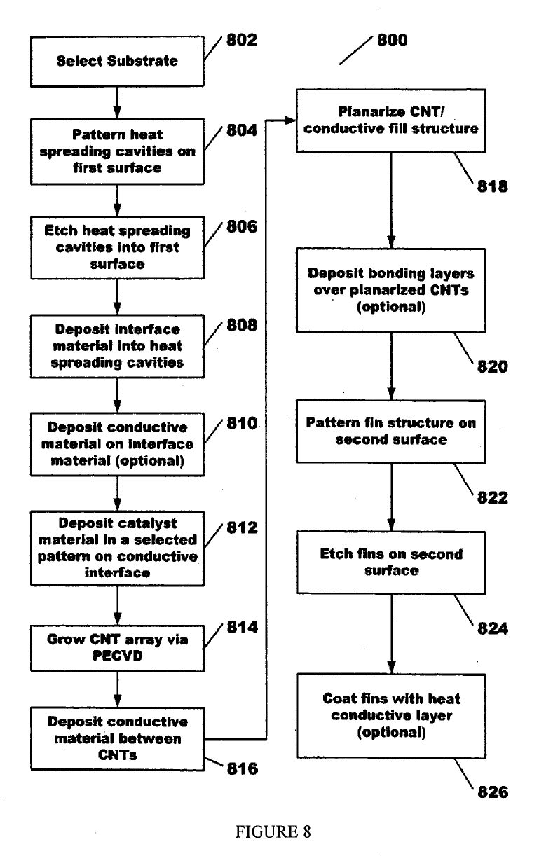

FIG. 8 is a process flow diagram 800 illustrating exemplary steps for manufacture of a finned integrated micro-cooler device according to an embodiment of the invention. At step 802, a suitable material is selected for the substrate or heat sink body, e.g. 404. The subsequent steps refer to a process where silicon is chosen as the substrate. At step 804, heat spreading cavities, e.g. 416, are patterned in a first (or bottom) surface. At step 806, the heat spreading cavities are etched, and at step 808, an interface material, e.g. 412 is deposited in the cavities e.g. 416. As previously mentioned, this interface material is silicon nitride in some embodiments. Numerous techniques are known to those skilled in the art to deposit silicon nitride, examples of which are CVD, or sputtering. Alternatively, the heat spreading cavities can be fabricated by machining if the heat sink body material is chosen to be a metal or ceramic. At step 810, an optional conductive layer is deposited over the interface layer to facilitate the deposition and adhesion of the subsequent catalyst layer. The conductive layer is preferrably composed of Ti, Cr, or Pt with thickness in the range of 3 nm-200 nm. If the heat sink body is metal, a conductive layer may not be required. At step 812, a catalyst material chosen from among Ti, Co, Cr, Pt, Ni, and their alloys is deposited using CVD, PVD, electroplating or electroless deposition to a layer thickness of 3 nm to 30 nm. At step 814, a carbon nanotube array e.g. as part of layer 408 of individually separated carbon nanotubes is grown. In some embodiments, the array is grown via PECVD per the method of J. Li and A. Delzeit referenced previously. At step 816, a thermally conductive material is deposited between the carbon nanotubes. For a thermally conductive material that is a metal, the material is typically deposited by electrochemical deposition or CVD, as is known to those skilled in the art. If a CVD diamond interstitial material is used, CVD processes known in the art can be used. At step 818, the carbon nanotube containing layer e.g. 408 is planarized by CMP, electrochemical etching, or a combination of both. At step 820, an optional eutectic bonding layer e.g. 406, of appropriate thickness is added if desired. At step 822, fins, e.g. 414 are patterned in a second (or top) surface for silicon substrates. At step 824, the fins are etched by well known methods. At step 826, the fins are coated with an optional metal coating or CVD diamond, deposited at the appropriate thickness required to minimize temperature gradients along the fins' surfaces. For the case of a metal heat sink body, e.g. 404, the fins are fabricated by well known machining processes.

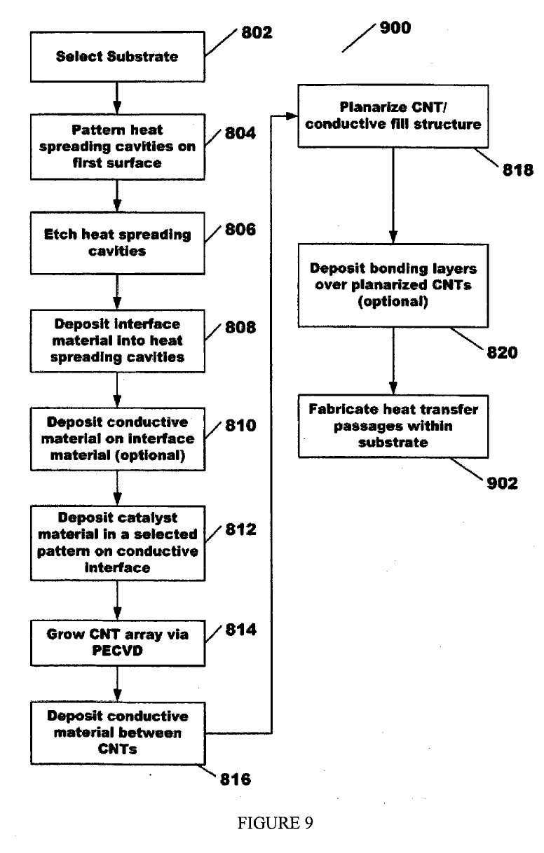

FIG. 9 is a process flow diagram 900 illustrating examplary steps for manufacture of an integrated micro-cooler device having internal flow channels according to an embodiment of the invention. At step 902, the flow passages, e.g. 514 are fabricated in the heat transfer body, e.g. 504. For metal bodies, standard machining techniques can be used. For silicon substrates, fins may be fabricated as described in the embodiments shown in FIG. 8. A suitable metal, ceramic, or silicon plate or cover is adhesively bonded to the top, flat surfaces of the fins to create enclosed passages, e.g. 514.

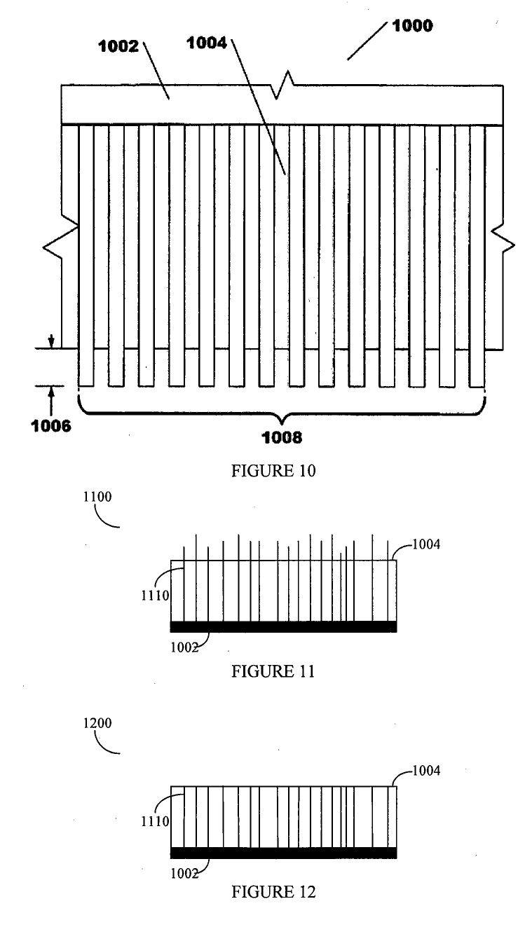

FIG. 10 is a partial cross section view 1000 of the nano-structure array subsequent to a planarization process according to an embodiment of the invention. Carbon nanotubes or nanowires 1008 are grown from the metal/catalyst layer 1002 in an approximately parallel structure as shown. As previously described, a thermally conductive filler material 1004 is placed in the voids between the nano-strucures 1008. Planarization of the nano-structures produces a gap 1006 between the ends of the nano-structures and the recessed planarized surface of the filler material. Gap 1006 results from a chemical-mechanical planarization (CMP) process when a composite material containing components of significantly different hardness is planarized. In the case where the nano-structures are MWCNTs and the filler is a metal such as copper, aluminum, or silver, the planarization process undercuts the filler because the metal is much softer than the carbon nanotubes. The same effect can be created by chemical or electrochemical etching of the filler metal because base metals, such as copper, are more reactive and susceptible to chemical dissolution than the relatively chemically inert carbon nanotubes.

The unsupported nano-structures in the gap 1006 are relatively flexible, allowing the exposed ends to twist and bend on a micron scale to conform to undulations and imperfections in the heat generating surface of the integrated circuit chip. This hair brush effect produces intimate contact with the ends of the nano-structures, allowing heat extraction along the axis of the nanotubes, where their thermal conductivity is the greatest. If a eutectic or bonding layer is used, the exposed ends of the nano-structures protrude into this layer, and are allowed to conform to the opposing surface when the eutectic or bonding layer is fluid, as would occur prior to bonding the two surfaces. The expected gap dimension 1006 depends on the surface flatness of the circuit, silicon die and of the planarized micro-cooler surface. The RMS value of the surface asperity is believed to lie in the range of 0.2 um to 3 um with preferred values being at the lower end of the range. Therefore, in an embodiment of the invention and as further seen in exemplary and non-limiting cross section 1100 of FIG. 11, the carbon nanotubes 1110 growing from substrate 1002 are protruding over the surface of the filler material 1004 at different lengths. The carbon nanotubes are generally grown in the desired heat transfer axis to enable a thermal interface from a hot spot. To overcome the potential reduction of the thermal conductivity between a micro-cooler and a heat sink the following steps are disclosed.

FIG. 12 shows an exemplary schematic cross-section 1200 of the disclosed apparatus, or micro-cooler, with the carbon nanotubes 1110 cut to uniform length over the surface of the filler material 1004. The filler material includes, but is not limited to, copper and copper alloys. Other non-metallic filler material that wet CNT arrays and get sucked by capillary forces into the air interspace interstial to nanotubes are:
a) wax-paraffin;
b) polymers with low viscosity, e.g. <200 centipoise, and/or, with low Young's module, e.g. <1 psi;
c) any other low Young's module material, e.g. silicone gel, seeded with nano-particles, e.g. silver, with diameters much smaller than the spacing of the individually separated and relatively parallel nanotubes.

It is important that the carbon nanotubes or nanofibers are individually separated and parallel before or as a results of the embedding of the filler material. Spin coating is used to accomplish the same result as capillary forces. In accordance with the disclosed invention, the exposed carbon nanotubes 1110 are cut closely to the surface of the filler material 1004 using various methods. Cutting methods include, but are not limited to, oxidation where oxygen is used to burn the exposed carbon nanotubes while the buried part of the carbon nanotubes is protected by the filler material 1004. Another cutting method is mechanical polishing, where the carbon nanotubes are mechanically removed back to the surface of the filler material. Yet another cutting method uses chemical etching, where the carbon nanotubes are chemically removed above the surface of the filler material.

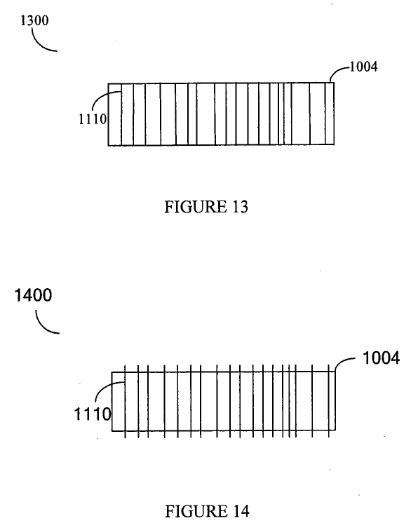

FIG. 13 shows an exemplary schematic cross-section 1300 of the disclosed apparatus, where the substrate 1002 has been removed by chemical or mechanical means. The carbon nanotubes 1110 for both opposite surfaces essentially reach the surface.

FIG. 14 shows an exemplary schematic cross-section 1400 of the apparatus, where the carbon nanotubes 1110 are exposed to essentially a uniform length over the partially removed filler material 1004. After the cutting of the carbon nanotubes 1110 to essentially the level of the filler material 1004 surface of one surface, and removing the substrate 1002 covering the opposite surface, the surfaces of the filler material 1004 are partially removed, using a selective removal process, thereby exposing the edges of the carbon nanotubes 1110. As a result the edges of the carbon nanotubes 1110 of the apparatus protrude beyond each of the opposite surfaces of the filler material 1004 at essentially the same length, thereby providing the advantages sought for by the disclosed invention. The apparatus is a thermal interface structure, enabling an effective thermal path between a hot surface and a cooling surface. The invention thereby enables connection on both sides using the advantages of the heat transfer capabilities of carbon nanotubes by providing an advantageous conducting path, using the appropriate pressure. The application of appropriate pressures is discussed in detail in U.S. patent application Ser. No. 11/207,096, entitled An Apparatus and Test Device for the Application and Measurement of Prescribed, Predicted and Controlled Contact Pressure on Wires, assigned to common assignee, and which is incorporated by reference for all the information it contains.

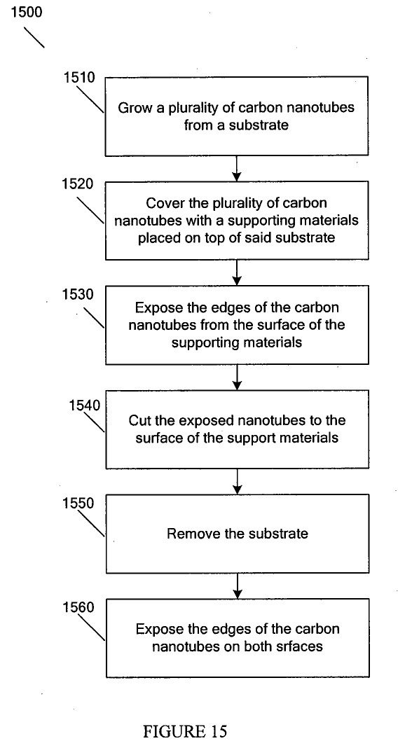

FIG. 15 shows an exemplary and non-limiting flowchart 1500 of the method for creating the apparatus of carbon nanotubes of essentially equal length. In step 1510, a plurality of carbon nanotubes is grown on a substrate, for example a silicon wafer or copper, using methods that are well known in the art. In step 1520, the plurality of carbon nanotubes is filled and covered with a filler material such as, but not limited to, electro-chemically-deposited (ECD) copper, forming, for example the filler material 1004. In step 1530, the edges of the carbon nanotubes are exposed using methods well known in the art, such as electro-chemical polishing (ECP) chemical-mechanical polishing (CMP), or plasma etching of the excess material and or of the nanotube ends. Specifically, immersing the nanotubes in the filler material, perferably in a soft, semi-liquid form, then allowing for solidification of the filler material at lower temperature followed by etching of excess filler material and nanotubes edges to provide smooth nanotubes, and a filler material surface with a roughness of less than 100 nanometers peak to peak. In the case where the filler material is made of wax-paraffin or a phase change material, the surface smoothness is obtained from pressing the edges of the surface of the filler material against another flat surface, e.g. glass or copper plate, while heating the structure to above its melting point followed by cooling the structure so that the filler material enters its solid phase.

In step 1540, the edges of the carbon nanotubes are cut to substantially the same length over the surface of the supporting medium, for example, the filler material 1004. Cutting methods include, but are not limited to, oxidation where oxygen is used to burn the exposed carbon nanotubes while the buried part of the carbon nanotubes is protected by the support medium, for example, the filler material 1004. In step 1550, the substrate is removed by chemical or mechanical means, exposing a second surface that is opposite to the first surface of filler material 1004. Such a process removes the substrate but generally leaves the filler material 1004 intact, as well as the carbon nanotubes contained therein.

In step 1560, the edges of the carbon nanotubes on both the upper and lower surfaces of filler material 1004 are exposed by selectively removing a portion of the surface of the support medium, for example, the filler material 1004, using a selective removal process. Such a process removes the support medium but generally leaves the carbon nanotubes that are of a different material intact, thereby exposing the edges of the carbon nanotubes from the surface of the support medium. The end result is a heat conductor comprised of carbon nanotubes embedded in a support medium, where the carbon nanotubes protrude essentially the same length beyond the opposite surfaces of the support medium. While the description herein refers to step 1550 as partially removing the filler material 1004 on both opposite surfaces, a person skilled in the art would realize that this step may be achieved by two steps, each step dealing with one surface. In one embodiment of the disclosed invention the second surface is exposed, after which the carbon nanotubes of that surface, including the nuclei sites are exposed and then cut. These steps are performed only on the second surface 1550 to expose the carbon nanotubes to essentially the same length beyond the second surface. In another embodiment of the invention, one surface is exposed such that the carbon nanotubes of that surface protrude to a length beyond the surface which is larger than the protrusion of the carbon nanotubes over the opposite surface.

The various embodiments described above should be considered as merely illustrative of the invention. They are not intended to be exhaustive or to limit the invention to the forms disclosed. Those skilled in the art will readily appreciate that still other variations and modifications may be practiced without departing from the general spirit of the invention set forth herein. Therefore, it is intended that the present invention be defined by the Claims that follow.

1. A micro-cooler device structure comprising:
a heat sink body having a heat sink surface;
a plurality of individually separated, rod-like nano-structures for transferring thermal energy from a surface of at least one integrated circuit chip to said heat sink surface, said plurality of individually separated, rod-like nano-structures being disposed between said heat sink surface and said surface of at least one integrated circuit chip, said rod like nano-structures protruding at an essentially identical length from each of opposite surfaces of said micro-cooler device; and
a thermally conductive material disposed within interstitial voids between said plurality of individually separated, rod-like nano-structures.

2. A micro-cooler device as recited in claim 1, wherein said plurality of individually separated, rod-like nano-structures comprise multi-walled carbon nanotubes.

3. A micro-cooler device as recited in claim 1, wherein said plurality of individually separated, rod-like nano-structures comprise metallic nano-wires.

4. A micro-cooler device as recited in claim 3, wherein said metallic nano-wires are oriented substantially perpendicular to said at least one integrated circuit chip surface.

5. A micro-cooler device as recited in claim 1, wherein said thermally conductive material comprises any of copper, alloys of copper, silver, aluminum, phase change material, polymer, and silicone gel.

6. A micro-cooler device as recited in claim 1, wherein said heat sink body is cooled by any fins and a liquid flowing through passages fashioned therein.

7. A micro-cooler device as recited in claim 1, wherein said plurality of individually separated, rod like nano-structures have a surface coverage density between 15 and 40 percent.

8. A method for fabricating a micro-cooler device, comprising the steps of:
fashioning a heat spreading cavity in a mounting surface of a heat sink body;
growing individually separated rod-like nano-structures within said cavity;
depositing a thermally conductive material in interstitial voids between said rod-like nano-structures;
removing a substrate from which said rod-like nano-structures are grown; and
exposing said rod-like nano-structures from opposite surfaces of said thermally conductive material.

9. A method for fabricating a micro-cooler device as recited in claim 8, further comprising the step of:
cutting said exposed edges of said rod-like nano-structures; and
exposing ends of said rod-like nano-structures.

10. A method for fabricating a micro-cooler device as recited in claim 8, wherein said rod-like nano-structures comprise multi-walled carbon nano-tubes.

11. A method for fabricating a micro-cooler device as recited in claim 8, wherein said rod-like nano-structures comprise metallic nano-wires.

12. A method for fabricating a micro-cooler device as recited in claim 8, wherein said thermally conductive material comprises any of copper, copper alloy, aluminum, silver, phase change material, polymer, and silicone gel.

13. A method for fabricating a micro-cooler device as recited in claim 8, wherein said rod-like nano-structures are individually separated, and oriented substantially perpendicular to said mounting surface of said heat sink body.

14. A method for fabricating a micro-cooler device as recited in claim 8, further comprising the step of:
depositing a bonding layer over the ends of said rod-like nano-structures.

15. A method for fabricating a micro-cooler device as recited in claim 8, wherein said plurality of individually separated, rod like nano-structures have a surface coverage density between 15 and 40 percent.

16. A method for achieving substantially identical protrusion of carbon nanotubes over opposite surfaces, comprising the steps of:
growing a plurality of carbon nanotubes from a substrate;
placing a filler material over said plurality of carbon nanotubes;
exposing said plurality of carbon nanotubes from a filler material surface;
removing the substrate;
cutting exposed carbon nanotubes; and
exposing edges of said plurality of carbon nanotubes of each of said opposite surfaces.

17. A method for achieving substantially identical protrusion of carbon nanotubes over opposite surfaces as recited in claim 16, further comprising the step of:
polishing the surface of said filler material after cutting said carbon nanotubes.

18. A method for achieving substantially identical protrusion of carbon nanotubes over opposite surfaces as recited in claim 16, wherein said step of cutting exposed nanotubes comprises any of oxidation, mechanical polishing, chemical polishing, and plasma etching.

19. A method for achieving substantially identical protrusion of carbon nanotubes over opposite surfaces as recited in claim 16, wherein said filler materials comprises any of copper, copper alloy, aluminum, silver, phase change material, polymer, and silicone gel.

20. A method for achieving substantially identical protrusion of carbon nanotubes over opposite surfaces as recited in claim 16, wherein said step of placing a filler material comprises the step of:
depositing said filler material.

21. A method for achieving substantially identical protrusion of carbon nanotubes over opposite surfaces as recited in claim 20, wherein said step of depositing said filler material comprises:
electrochemical deposition of said filler material.

22. A method for achieving substantially identical protrusion of carbon nanotubes over opposite surfaces as recited in claim 16, further comprising the step of:
exposing carbon nanotubes from the surface previously covered by said substrate.

23. A method for achieving substantially identical protrusion of carbon nanotubes over opposite surfaces as recited in claim 16, wherein the step of exposing the edges of said plurality of carbon nanotubes comprises the step of:
exposing the edges of the carbon nanotubes of one surface to a greater length than that of an opposite surface.

24. A method for achieving substantially identical protrusion of carbon nanotubes over opposite surfaces as recited in claim 16, wherein said plurality of carbon nanotubes have a surface coverage density between 15 and 40 percent.

25. A heat conducting method comprising the steps of:
providing a plurality of carbon nanotubes protruding from opposite surfaces of a filler material, the protrusion of each of said carbon nanotubes from said surface of said filler material being substantially identical; and
the step of placing substantially identical protrusion over said surface achieved by the steps of cutting exposed carbon nanotubes protruding above a surface of the filler material; and
removing a portion of each of the opposite surfaces to expose said carbon nanotubes at each surface.

26. A heat conducting method as recited in claim 25, wherein after cutting said exposed carbon nanotubes a step of polishing of said surface and said carbon nanotubes is performed.

27. A heat conducting method as recited in claim 25, wherein said cutting the exposed carbon nanotubes step comprises any of: oxidation, mechanical polishing, chemical polishing, and plasma etching.

28. A heat conducting method as recited in claim 25, wherein said filler material comprises any of copper, copper alloy, aluminum, silver, phase change material, polymer, and silicone gel.

29. A heat conducting method as recited in claim 25, wherein said substrate comprises any of silicon wafer, copper, and metal coated ceramic.

30. A heat conducting method as recited in claim 25, wherein the protrusion of the exposed carbon nanotubes over one surface is larger than the protrusion of the exposed carbon nanotubes over a opposite surface.

31. A heat conducting method as recited in claim 25, wherein said plurality of carbon nanotubes have a surface coverage density between 15 and 40 percent.

32. A thermal interface structure, comprising:
a plurality of carbon nanotubes in an orientation substantially parallel to a desired heat transfer axis of a thermal interface; and
a filler material positioned around the plurality of carbon nanotubes;
the edges of the plurality of carbon nanotubes protruding at an essentially identical height above each of opposite surfaces of said filler material.

33. A thermal interface structure as recited in claim 32, wherein said filler material comprises any of copper, copper alloy, aluminum, silver, phase change material, polymer, and silicone gel.

34. A thermal interface structure as recited in claim 32, wherein said substrate comprises any of silicon wafer, and copper.

35. A thermal interface structure as recited in claim 32, wherein the protrusion of the exposed carbon nanotubes over one surface is larger than the protrusion of the exposed carbon nanotubes over a opposite surface.

36. A heat conducting apparatus as recited in claim 25, wherein said plurality of carbon nanotubes have a surface coverage density between 15 and 40 percent.
